(19) United States
(12) Patent Application Publication
(10) Pub. No.: US 2024/0192555 A1
(43) Pub. Date: Jun. 13, 2024

(54) DISPLAY PANEL

(71) Applicant: WUHAN CHINA STAR OPTOELECTRONICS TECHNOLOGY CO., LTD., Wuhan (CN)

(72) Inventor: Guiyang ZHANG, Wuhan (CN)

(21) Appl. No.: 18/458,833

(22) Filed: Aug. 30, 2023

(30) Foreign Application Priority Data
Dec. 7, 2022 (CN) 202223281064.2

(51) Int. Cl. G02F 1/1362; G02F 1/1335; H01L 27/12

(52) U.S. Cl. CPC G02F 1/136209; G02F 1/133514; H01L 27/124

(57) ABSTRACT

A display panel includes a backlight module, a color filter substrate disposed on a side of the backlight module, and an array substrate disposed on a side of the color filter substrate away from the backlight module. The array substrate includes a first substrate, a metal layer disposed on a side of the first substrate close to the backlight module, and a first light-shielding layer disposed on a surface of a side of the metal layer close to the backlight module.

### CROSS REFERENCE TO RELATED APPLICATIONS

This application claims priority to Chinese Patent Application No. 202223281064.2, filed on Dec. 7, 2022, and entitled “DISPLAY PANEL”. The entire disclosures of the above application are incorporated herein by reference.

### TECHNICAL FIELD

The present application relates to the field of display technology, in particular to a display panel.

### BACKGROUND

The development of display technology is changing with each passing day, from cathode ray tube (referred to as CRT) display to liquid crystal display, organic light-emitting diode (referred to as OLED) display and submillimeter light-emitting diode (mini LED) display launched in the past two years have been mass-produced. The layout of future micron light-emitting diode (micro LED) displays is also accelerating. Although the display industry is becoming more and more diversified, the main indicators of display technology have not changed. Manufacturers are still pursuing changes in brightness, chromaticity, contrast, screen-to-body ratio, and appearance, such as curved screens, hole-digging screens, flexible screens, folding screens, etc.

The improvement of display brightness is an eternal pursuit, especially for liquid crystal display (LCD for short). A liquid crystal display uses a combination of a polarizer and a liquid crystal to display through a backlight source. The transmittance of commonly used LCD products with a resolution of 400 PPI (pixels per inch) is about 5%, and brightness efficiency is extremely low. When a resolution increases, an aperture ratio may decrease, and a product transmittance may further decrease. While reducing the brightness, power consumption may increase, and a battery life may decrease. This is not conducive to the application of ultra-high resolution products, such as virtual reality (VR for short).

### SUMMARY

The present application provides a display panel, which can solve the issues existing in current display panels such as low transmittance, low light energy utilization rate, low brightness, increased power consumption, short battery life, and unfavorable application of ultra-high resolution products.

In order to solve the above issues, the present application provides a display panel, which includes:
a backlight module; a color filter substrate disposed on a side of the backlight module; and an array substrate disposed on a side of the color filter substrate away from the backlight module; wherein the array substrate comprises: a first substrate; a metal layer disposed on a side of the first substrate close to the backlight module; and a first light-shielding layer disposed on a surface of a side of the metal layer close to the backlight module.

Furthermore, in some embodiments, the array substrate further comprises: a second light-shielding layer disposed on a surface of a side of the metal layer away from the backlight module.

Furthermore, in some embodiments, both a reflectance of the first light-shielding layer and a reflectance of the second light-shielding layer are less than 10%.

Furthermore, in some embodiments, the array substrate further comprises: a first active layer disposed on a side of the first substrate close to the backlight module; a first source-drain layer disposed on a side of the first active layer close to the backlight module, wherein the first source-drain layer comprises a first source and a first drain electrically connected to both ends of the first active layer; a second active layer disposed on the same layer as the first active layer at intervals; a second source-drain layer disposed on the same layer as the first source-drain layer at intervals, wherein the second source-drain layer comprises a second source and a second drain electrically connected to both ends of the second active layer; wherein the metal layer comprises at least one of the first source-drain layer and the second source-drain layer.

Furthermore, in some embodiments, when a material of the first light-shielding layer is an insulating material, a first through hole is provided on the first light-shielding layer on the first drain; when a material of the first light-shielding layer is a conductive material, the array substrate further comprises a first insulating layer disposed between the metal layer and the first light-shielding layer, a second through hole is provided on the first insulating layer between the first drain and the first light-shielding layer, and the first drain is electrically connected to the first light-shielding layer through the second through hole.

Furthermore, in some embodiments, the array substrate further comprises: a first gate disposed on the side of the first active layer close to the backlight module, and disposed corresponding to the first active layer; a second gate disposed on the same layer as the first gate at intervals, and disposed corresponding to the second active layer; when a material of the first light-shielding layer is an insulating material, a third through hole is provided on the first light-shielding layer on the second gate; when the material of the first light-shielding layer is a conductive material, the array substrate further comprises a first insulating layer disposed between the metal layer and the first light-shielding layer, a fourth through hole is provided on the first insulating layer between the second gate and the first light-shielding layer, and the second gate is electrically connected to the first light-shielding layer.

Furthermore, in some embodiments, the first light-shielding layer and the second light-shielding layer on the first gate and the second gate comprise a molybdenum oxide film layer.

Furthermore, in some embodiments, the first light-shielding layer and the second light-shielding layer on the first source, the first drain, the second source, and the second drain comprise a molybdenum film layer and the molybdenum oxide film layer; a thickness of the molybdenum oxide film layer and a total thickness range of the molybdenum film layer ranges from 100 nm to 150 nm; a ratio range of the thickness of the molybdenum oxide film layer to a thickness of the molybdenum film layer ranges from ⅙ to ½.

Furthermore, in some embodiments, the color filter substrate comprises: a second substrate; a reflective layer disposed on a side of the second substrate away from the backlight module; a third light-shielding layer disposed on a side of the reflective layer away from the backlight module; a plurality of openings penetrating through the third light-shielding layer and the reflective layer; and a plurality of filter units filling the plurality of openings in a one-to-one correspondence.

Furthermore, in some embodiments, a projection of the reflective layer on the second substrate coincides with a projection of the third light-shielding layer on the second substrate.

Furthermore, in some embodiments, a reflectance of the reflective layer is greater than 60%.

The present application provides a display panel, which includes:
a backlight module; a color filter substrate disposed on a side of the backlight module; and an array substrate disposed on a side of the color filter substrate away from the backlight module; wherein the array substrate comprises: a first substrate; a metal layer disposed on a side of the first substrate close to the backlight module; and a first light-shielding layer disposed on a surface of a side of the metal layer close to the backlight module, wherein a reflectance of the first light-shielding layer is less than 10%.

Furthermore, in some embodiments, the array substrate further comprises: a second light-shielding layer disposed on a surface of a side of the metal layer away from the backlight module, wherein a reflectance of the secondlight-shielding layer is less than 10%.

Furthermore, in some embodiments, the array substrate further comprises: a first active layer disposed on a side of the first substrate close to the backlight module; a first source-drain layer disposed on a side of the first active layer close to the backlight module, wherein the first source-drain layer comprises a first source and a first drain electrically connected to both ends of the first active layer; a second active layer disposed on the same layer as the first active layer at intervals; a second source-drain layer disposed on the same layer as the first source-drain layer at intervals, wherein the second source-drain layer comprises a second source and a second drain electrically connected to both ends of the second active layer; wherein the metal layer comprises at least one of the first source-drain layer and the second source-drain layer.

Furthermore, in some embodiments, when a material of the first light-shielding layer is an insulating material, a first through hole is provided on the first light-shielding layer on the first drain; when a material of the first light-shielding layer is a conductive material, the array substrate further comprises a first insulating layer disposed between the metal layer and the first light-shielding layer, a second through hole is provided on the first insulating layer between the first drain and the first light-shielding layer, and the first drain is electrically connected to the first light-shielding layer through the second through hole.

Furthermore, in some embodiments, the array substrate further comprises: a first gate disposed on the side of the first active layer close to the backlight module, and disposed corresponding to the first active layer; a second gate disposed on the same layer as the first gate at intervals, and disposed corresponding to the second active layer; when a material of the first light-shielding layer is an insulating material, a third through hole is provided on the first light-shielding layer on the second gate; when the material of the first light-shielding layer is a conductive material, the array substrate further comprises a first insulating layer disposed between the metal layer and the first light-shielding layer, a fourth through hole is provided on the first insulating layer between the second gate and the first light-shielding layer, and the second gate is electrically connected to the first light-shielding layer.

Furthermore, in some embodiments, the first light-shielding layer and the second light-shielding layer on the first gate and the second gate comprise a molybdenum oxide film layer; the first light-shielding layer and the second light-shielding layer on the first source, the first drain, the second source, and the second drain comprise a molybdenum film layer and the molybdenum oxide film layer; a thickness of the molybdenum oxide film layer and a total thickness range of the molybdenum film layer ranges from 100 nm to 150 nm; a ratio range of the thickness of the molybdenum oxide film layer to a thickness of the molybdenum film layer ranges from ⅙ to ½.

Furthermore, in some embodiments, the color filter substrate comprises: a second substrate; a reflective layer disposed on a side of the second substrate away from the backlight module; a third light-shielding layer disposed on a side of the reflective layer away from the backlight module; a plurality of openings penetrating through the third light-shielding layer and the reflective layer; and a plurality of filter units filling the plurality of openings in a one-to-one correspondence.

Furthermore, in some embodiments, a projection of the reflective layer on the second substrate coincides with a projection of the third light-shielding layer on the second substrate, and a reflectance of the reflective layer is greater than 60%.

Furthermore, in some embodiments, a reflectance of the third light-shielding layer is less than 10%, and a ratio range of an area of the third light-shielding layer to an area of the display panel is greater than or equal to 60%.

The present application has advantages that: the present application is provided with an array substrate on a side of the color filter substrate away from the backlight module. The first light-shielding layer is provided on a side of the metal layer of the array substrate close to the backlight module. The low reflectance of the first light-shielding layer is used to prevent light of the backlight module from being reflected to the liquid crystal layer after being irradiated by the color filter substrate to the metal layer of the array substrate. This avoids phenomenon of scattering caused by an uneven refractive index of the liquid crystal layer, avoids increasing a proportion of stray light, and improves a contrast of the display panel. The low reflectance of the first light-shielding layer is used to prevent the light of the backlight module from passing through the color filter substrate and irradiating to the vicinity of the channel of the thin film transistor behind the metal layer of the array substrate and reflected to the array substrate. This avoids switching leakage of the thin film transistors, which causes brightness crosstalk issues.

In the present application, the array substrate is arranged on the side of the color filter substrate away from the backlight module, and the second light-shielding layer is arranged on the side of the metal layer of the array substrate away from the backlight module. The low reflectance of the second light-shielding layer is used to prevent the phenomenon of glare caused by reflection after ambient light irradiates the metal layer in the array substrate, thereby improving the contrast of the display panel.

In the present application, the array substrate is disposed on the side of the color filter substrate away from the backlight module, and the reflective layer is disposed between the third light-shielding layer and the second substrate of the color filter substrate. The light irradiated to the third light-shielding layer in the prior art is reflected to the backlight module by utilizing the high reflectance of the reflective layer. The reflective sheet in the backlight module is reflected to the color filter substrate for reuse, thereby improving a light energy utilization rate of the backlight module. This improves brightness of the display panel, reduces power consumption, increases battery life, and is beneficial to an application of ultra-high resolution products.

### BRIEF DESCRIPTION OF THE DRAWINGS

In order to illustrate the technical solutions more clearly in the embodiments of the present application, the following briefly introduces the drawings that need to be used in the description of the embodiments. Obviously, the drawings in the following description are only some embodiments of the present application. For those skilled in the art, other drawings can also be obtained based on these drawings without any creative effort.

FIG. 1 is a schematic structural diagram of a display panel of the present application.

FIG. 2 is a bottom view of a color filter substrate of the present application.

FIG. 3 is a top view of a color filter substrate of the present application.

FIG. 4 is a side view of a reflective layer and a third light-shielding layer of a color filter substrate of the present application.

FIG. 5 is an optical path diagram of light of a backlight module between a color filter substrate and a reflective sheet of the present application.

FIG. 6 is a light path diagram when a second light-shielding layer is not provided on a side of a metal layer on an array substrate away from a backlight module of the present application.

FIG. 7 is a light path diagram when a second light-shielding layer is provided on a side of a metal layer on an array substrate away from a backlight module of the present application.

FIG. 8 is a light path diagram when the first light-shielding layer is not provided on a side of a metal layer on an array substrate close to a backlight module of the present application.

FIG. 9 is a light path diagram when a first light-shielding layer is provided on a side of a metal layer on an array substrate close to a backlight module of the present application.

FIG. 10 is a side view of a metal layer, a first light-shielding layer, and a second light-shielding layer of an array substrate of the present application.

FIG. 11 is an optical path diagram of a display panel of the present application.

FIG. 12 is a schematic structural view of an array substrate of the present application.

FIG. 13 is a top view of a metal layer of an array substrate of the present application.

### EXPLANATION OF REFERENCE NUMERALS

100 Display panel;
1 Backlight module; 2 First polarizer;
3 Color filter substrate; 4 Liquid crystal layer;
5 Array substrate; 6 Second polarizer;
7 Cover plate;
11 Bottom plate; 12 Reflective sheet;
13 Light source; 14 Light guide plate;
15 Optical film;
31 Second substrate; 32 Reflective layer;
33 Third light-shielding layer; 34 Opening;
35 Filter unit;
501 Metal layer; 502 First light-shielding layer;
503 Second light-shielding layer;
511 First substrate; 512 First active layer;
513 Light-shielding unit; 514 First gate;
515 First source-drain layer; 516 Second active layer;
517 Second gate; 518 Second source-drain layer;
519 Conductive unit; 520 Touch layer;
521 Common electrode; 522 Pixel electrode;
523 First through hole; 524 Third through hole;
525 Fifth through hole.

### DETAILED DESCRIPTION OF ILLUSTRATED EMBODIMENTS

The preferred embodiments of the present application will be described in detail below in conjunction with the accompanying drawings, so as to fully introduce the technical content of the present application to those skilled in the art. Examples are used to prove that the present application can be implemented, making the technical content disclosed in the present application clearer, and making it easier for those skilled in the art to understand how to implement the present application. However, the present application can be embodied in many different forms of embodiments. The protection scope of the present application is not limited to the embodiments mentioned in the text, and the description of the following embodiments is not intended to limit the scope of the present application.

The directional terms mentioned in the present application, such as “up”, “down”, “front”, “back”, “left”, “right”, “inside”, “outside”, “side”, etc., are only directions in the attached drawings. The directional terms used herein are used to explain and illustrate the present application, rather than to limit the protection scope of the present application.

In the drawings, components with the same structure are denoted by the same numerals, and components with similar structures or functions are denoted by similar numerals. In addition, the size and thickness of each component shown in the drawings are arbitrarily shown for ease of understanding and description. The present application does not limit the size and thickness of each component.

### Embodiment 1

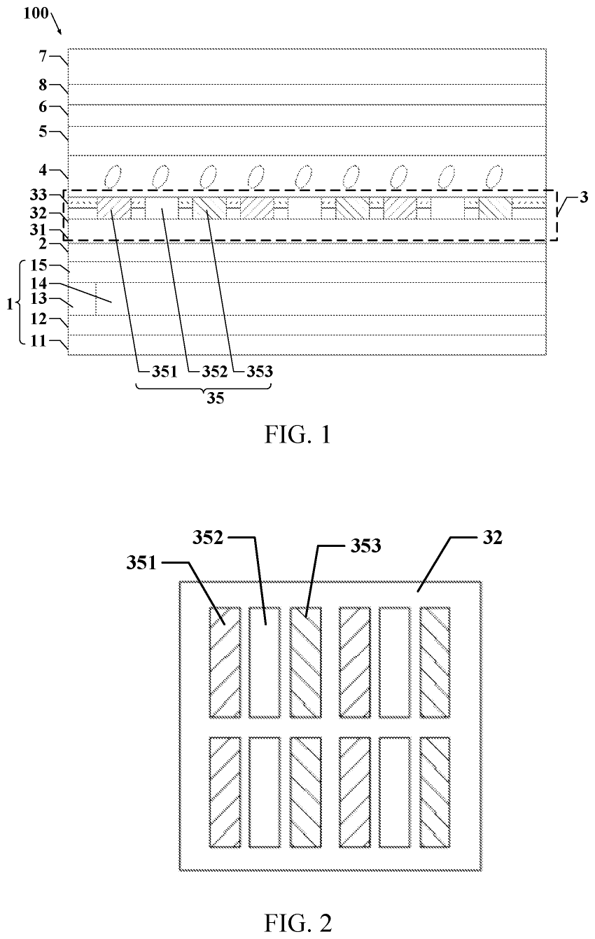

As shown in FIG. 1, this embodiment provides a display panel 100. The display panel 100 includes a backlight module 1, a first polarizer 2, a color filter substrate 3, a liquid crystal layer 4, an array substrate 5, a second polarizer 6, and a cover plate 7.

The display principle of the display panel 100 is that white light emitted by the backlight module 1 passes through the first polarizer 2 and becomes linearly polarized light. After being modulated by the liquid crystal layer 4, the polarization direction is rotated by 90°, and the white linearly polarized light passes through the color filter substrate 3 and becomes red, green, and blue light, and then emit through the second polarizer 6 with the same polarization direction to form pictures of different colors.

The backlight module 1 includes a bottom plate 11, a reflective sheet 12, a light source 13, a light guide plate 14, and an optical film 15.

The reflective sheet 12 is disposed on a side of the bottom plate 11 close to the color filter substrate 3. The reflective sheet 12 is mainly used to reflect the light irradiated to the reflective sheet 12, so as to improve light utilization rate of the backlight module 1 and increase display brightness of the display panel 100.

The light source 13 is disposed on the side of the reflective sheet 12 close to the color filter substrate 3 and is mainly used to provide light.

The light guide plate 14 is disposed on one side of the light source 13 and is mainly used to convert the light emitted by the light source 13 on the side of the light guide plate 14 into a surface light source to enter the optical film 15 above the light guide plate 14. In other embodiments, the backlight module 1 may also use a direct-type light source.

The optical film 15 is disposed on a side of the light guide plate 14 close to the color filter substrate 3. The optical film 15 includes a lower diffusion sheet, a prism sheet, and an upper diffusion sheet. The lower diffusion sheet is disposed on a side of the light guide plate 14 close to the color filter substrate 3. The prism sheet is arranged on the lower diffusion sheet. The upper diffusion sheet is arranged on the prism sheet. The lower diffusion sheet and the upper diffusion sheet can diffuse the light received by the light guide plate 14. The prism sheet can concentrate the diffused light and emit it within a certain angle, so as to achieve the purpose of improving the brightness of the display panel 100.

The first polarizer 2 is disposed on one side of the backlight module 1. Specifically, the first polarizer 2 is disposed on a side of the optical film 15 away from the bottom plate 11. The basic structure of the first polarizer 2 includes PVA (polyvinyl alcohol) and TAC (triacetyl cellulose) respectively arranged on both sides of the PVA. It is the PVA layer that plays a polarizing role, but PVA is very easy to hydrolyze. In order to protect the physical properties of the polarizing film, a layer of (TAC) film with high light transmittance, good water resistance, and certain mechanical strength is compounded on both sides of the PVA for protection.

The color filter substrate 3 is disposed on the side of the first polarizer 2 away from the backlight module. The color filter substrate 3 includes a second substrate 31, a reflective layer 32, a third light-shielding layer 33, a plurality of openings 34, and a plurality of filter units 35.

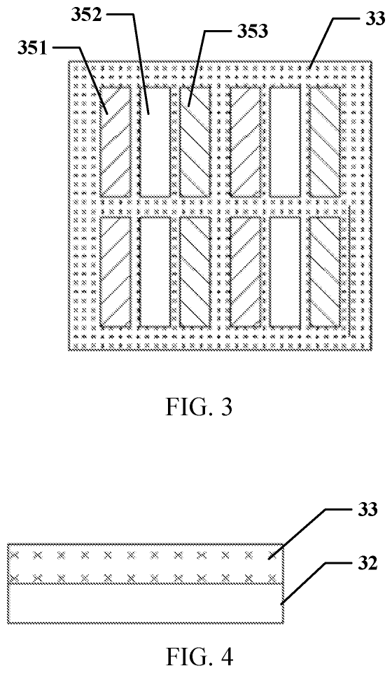

FIG. 2 is a bottom view of the color filter substrate 3, specifically referring to a schematic plan view of the color filter substrate 3 viewed from the side of the backlight module 1. FIG. 3 is a top view of the color filter substrate 3, specifically referring to a schematic plan view of the color filter substrate 3 viewed from the side of the array substrate 5. It can be seen from FIG. 1, FIG. 2, FIG. 3, and FIG. 4 that the reflective layer 32 is disposed on the side of the second substrate 31 away from the backlight module 1. Specifically, the reflective layer 32 is disposed between the third light-shielding layer 33 and the second substrate 31.

The reflectance of the reflective layer 32 is greater than 60%. The reflective layer 32 can be made of highly reflective metals such as aluminum and titanium, or highly reflective ink.

The third light-shielding layer 33 is disposed on a side of the reflective layer 32 away from the backlight module 1. The third light-shielding layer 33 is mainly used to prevent crosstalk of light from adjacent filter units 35. The reflectance of the third light-shielding layer 33 is less than 10%. The third light-shielding layer 33 can be formed by using BM photoresist material or can be formed by using blackened metal. The blackened metal can be a laminated structure of molybdenum oxide (MoOx), molybdenum (Mo) and molybdenum oxide; it can also be a laminated structure of molybdenum oxide (MoOx), aluminum (Al) and molybdenum oxide, or it can be molybdenum oxide (laminated structure of MoOx), titanium (Ti) and molybdenum oxide. The coherent and destructive effect between different film layers is used to reduce the interference light and improve the contrast of the display panel 100.

A plurality of openings 34 penetrate through the third light-shielding layer 33 and the reflective layer 32.

A plurality of filter units 35 fill the openings 34 one by one. In this embodiment, the filter unit 35 includes a red filter unit 351, a green filter unit 352, and a blue filter unit 353.

The projection of the reflective layer 32 on the second substrate 31 coincides with the projection of the third light-shielding layer 33 on the second substrate 31. In this embodiment, the projection of the reflective layer 32 on the second substrate 31 completely coincides with the projection of the third light-shielding layer 33 on the second substrate 31. In this way, the light passing through the third light-shielding layer 33 is prevented from being blocked by the reflective layer 32, and the light transmittance is improved.

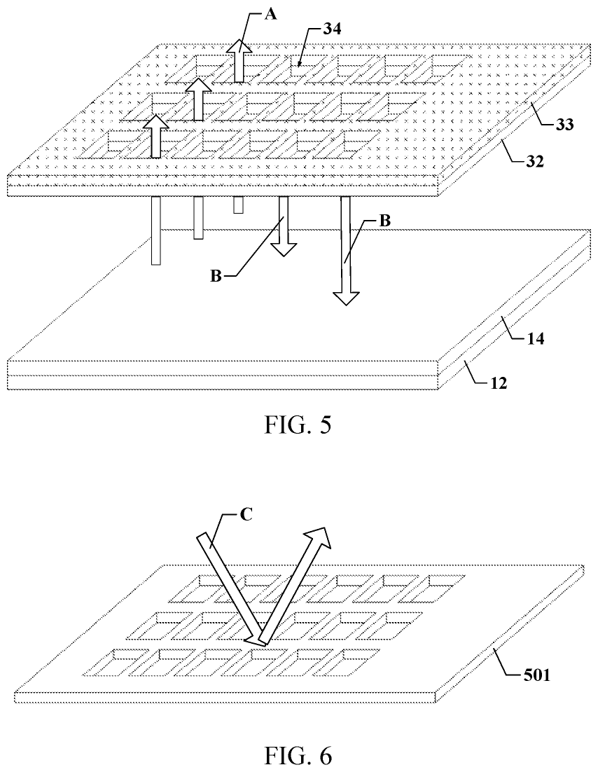

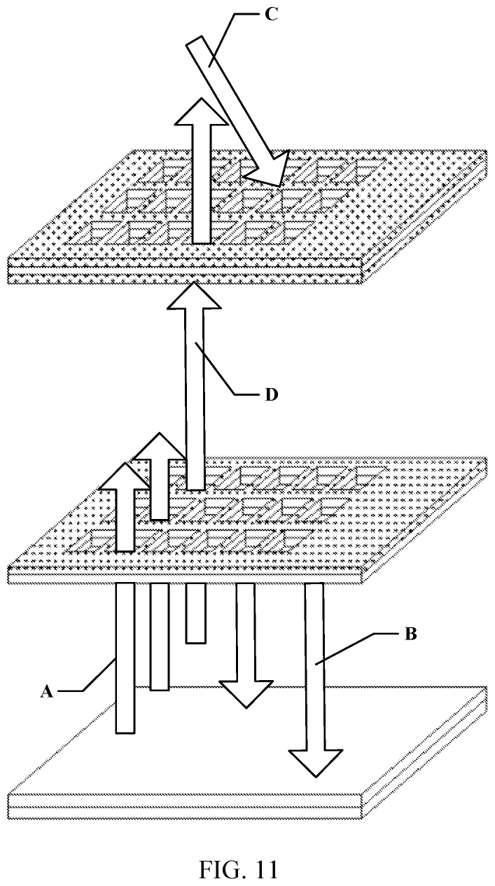

As shown in FIG. 5 and FIG. 11, an array substrate 5 is disposed on a side of the color filter substrate 3 away from the backlight module 1. A reflective layer 32 is provided between the third light-shielding layer 33 of the color filter substrate 3 and the second substrate 31. The first light A passes through the opening 34 and irradiates the filter unit 35, and then enters the liquid crystal layer 4. The second light B is irradiated to the reflective layer 32 around the opening 34 and is reflected by the reflective layer 32 to the reflective sheet 12 in the backlight module 1. The light irradiated to the third light-shielding layer 33 in the prior art is reflected into the backlight module 1 by utilizing the high reflectance of the reflective layer 32. The reflective sheet 12 in the backlight module 1 is reflected to the color filter substrate 3 for reuse, thereby improving the utilization rate of light energy of the backlight module 1. This improves the brightness of the display panel 100, reduces power consumption, and increases battery life, which is beneficial to the application of ultra-high resolution products. For example, in products such as VR, the resolution usually reaches more than 1500 ppi, and the area ratio of the third light-shielding layer 33 reaches more than 60%, which is more suitable for using the above-mentioned solution to increase brightness.

As shown in FIG. 1, the array substrate 5 is disposed on a side of the color filter substrate 3 away from the backlight module 1.

As shown in FIG. 6, the array substrate 5 includes a metal layer 501. Specifically, the metal layer 501 is disposed on a side of the first substrate 511 close to the backlight module 1. When the metal layer 501 on the array substrate 5 is not provided with the second light-shielding layer 503 on the side away from the backlight module 1, ambient light C irradiates the metal layer 501 and is reflected by the metal layer 501, which is likely to cause glare, resulting in a low contrast ratio of the display panel 100.

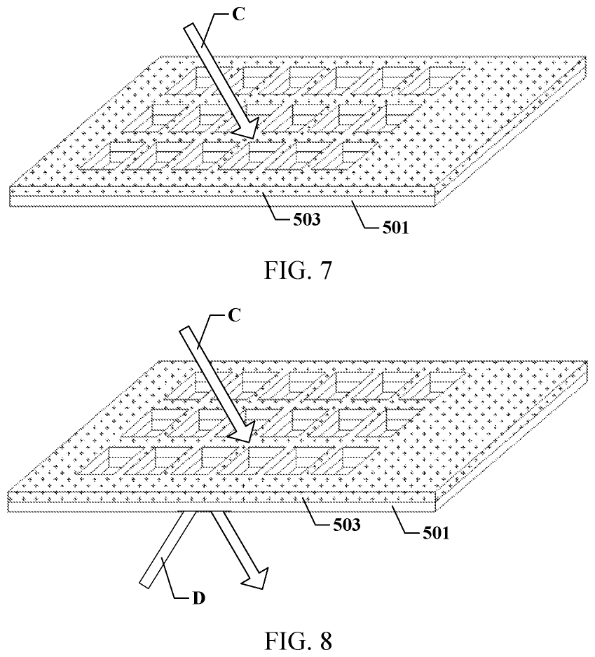

As shown in FIG. 7, FIG. 10, and FIG. 11, a second light-shielding layer 503 is disposed on a side of the metal layer 501 of the array substrate 5 away from the backlight module 1. The reflectance of the second light-shielding layer 503 is less than 10%. The second light-shielding layer 503 can be formed by using BM photoresist material or can be formed by using blackened metal. The blackened metal can be a laminated structure of molybdenum oxide (MoOx), molybdenum (Mo) and molybdenum oxide: it can also be a laminated structure of moly bdenum oxide (MoOx), aluminum (Al) and molybdenum oxide, or it can be molybdenum oxide (laminated structure of MoOx), titanium (Ti) and moly bdenum oxide. The coherent and destructive effect between different film layers is used to reduce the interference light and improve the contrast of the display panel 100. The low reflectance of the second light-shielding layer 503 reduces the reflection of ambient light on the surface of the metal layer 501, prevents glare caused by reflection after the ambient light irradiates the metal layer 501 in the array substrate 5, and improves the contrast of the display panel 100.

As shown in FIG. 8, the light D emitted by the backlight module 1 passing through the color filter substrate 3 is irradiated onto the metal layer 501 of the array substrate 5 and then reflected to the liquid crystal layer 4. Due to the non-uniform refractive index of the liquid crystal layer 4, scattering occurs, which increases the proportion of stray light and reduces the contrast of the display panel 100. The light D emitted by the backlight module 1 and passing through the color filter substrate 3 irradiates to the vicinity of the channels of the thin film transistors of the array substrate 5 after being reflected on the metal layer 501 of the array substrate 5. This causes the switch leakage of the thin film transistor, and the lax shutdown may easily lead to the brightness crosstalk issue.

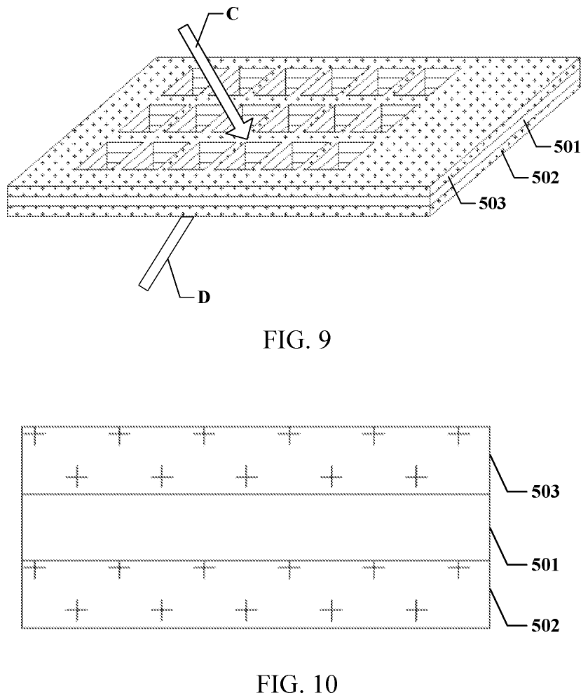

As shown in FIG. 9, FIG. 10, and FIG. 11, a first light-shielding layer 502 is disposed on a side of the metal layer 501 of the array substrate 5 close to the backlight module 1. The reflectance of the first light-shielding layer 502 is less than 10%. The first light-shielding layer 502 can be formed by using BM photoresist material or can be formed by using blackened metal. The blackened metal can be a laminated structure of molybdenum oxide (MoOx), molybdenum (Mo) and molybdenum oxide: it can also be a laminated structure of molybdenum oxide (MoOx), aluminum (Al) and molybdenum oxide, or it can be molybdenum oxide (laminated structure of MoOx), titanium (Ti) and molybdenum oxide. The coherent and destructive effect between different film layers is used to reduce the interference light and improve the contrast of the display panel 100. The low reflectance of the first light-shielding layer 502 is used to prevent the light from the backlight module 1 from passing through the color filter substrate 3 irradiating to the metal layer 501 of the array substrate 5 and then being reflected to the liquid crystal layer 4. This avoids the phenomenon of scattering caused by the uneven refractive index of the liquid crystal layer 4, avoids increasing the proportion of stray light, and improves the contrast of the display panel. The low reflectance of the first light-shielding layer 502 is used to prevent light from the backlight module 1 passing through the color filter substrate 3 from being irradiated to the vicinity of the TFT channels of the array substrate 5 after being reflected to the metal layer 501 of the array substrate 5. This avoids the switch leakage of the thin film transistor and avoids the brightness crosstalk issue.

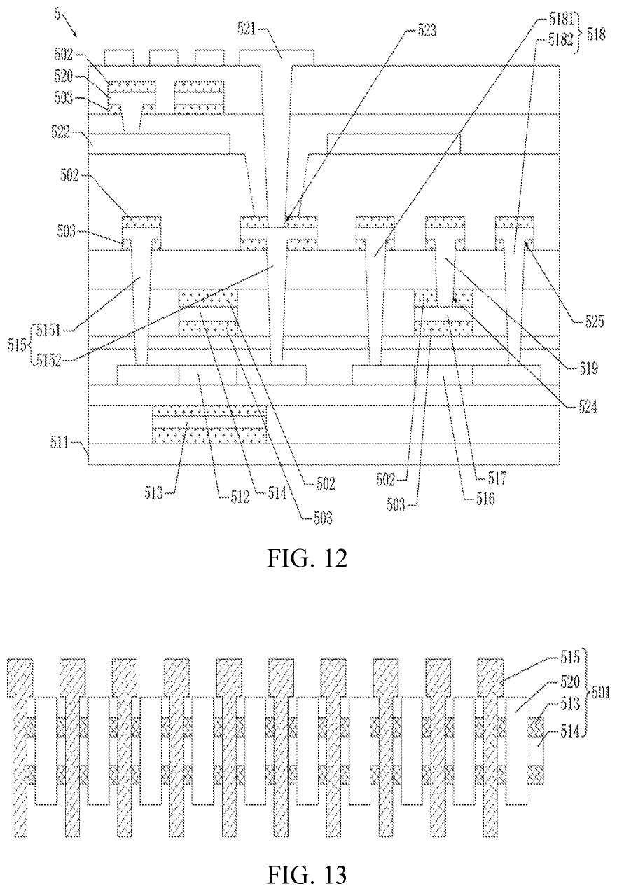

As shown in FIG. 12 and FIG. 13, the array substrate 5 includes a first substrate 511, a first active layer 512, a light-shielding unit 513, a first gate 514, a first source-drain layer 515, a second active layer 516, a second gate 517, a second source-drain layer 518, a conductive unit 519, a touch layer 520, a common electrode 521, and a pixel electrode 522.

The first active layer 512 is disposed on a side of the first substrate 511 close to the backlight module 1.

The light-shielding unit 513 is disposed between the first active layer 512 and the first substrate 511. The light-shielding unit 513 is mainly used to prevent light from irradiating the first active layer 512 and avoid affecting the array substrate 5.

The first gate 514 is disposed on a side of the first active layer 512 close to the backlight module 1.

The first source-drain layer 515 is disposed on a side of the first gate 514 close to the backlight module 1. The first source-drain layer 515 includes a first source 5151 and a first drain 5152 respectively electrically connected to two ends of the first active layer 512.

The second active layer 516 is in the same layer as the first active layer 512 and arranged at intervals.

The second gate 517 is arranged on the same layer as the first gate 514 at intervals and is arranged corresponding to the second active layer 516.

The second source-drain layer 518 is in the same layer as the first source-drain layer 515 and arranged at intervals. The second source-drain layer 518 includes a second source 5181 and a second drain 5182 respectively electrically connected to two ends of the second active layer 516.

The conductive unit 519 is disposed between the second source 5181 and the second drain 5182, is disposed on the same layer as the second source 5181, and is electrically connected to the second gate 517.

The touch layer 520 is disposed on a side of the first source-drain layer 515 close to the backlight module 1.

The common electrode 521 is disposed on a side of the touch layer 520 away from the backlight module 1. The common electrode 521 may be made of indium tin oxide (ITO).

The pixel electrode 522 is disposed on a side of the touch layer 520 close to the backlight module 1. The pixel electrode 522 can be formed by using indium tin oxide (ITO). The pixel electrode 522 is electrically connected to the first drain 5152.

As shown in FIG. 12, the metal layer 501 includes at least one of the light-shielding unit 513, the first gate 514, the first source-drain layer 515, the second gate 517, the second source-drain layer 518, the conductive unit 519, and the touch layer 520. In this embodiment, the metal layer 501 includes the light-shielding unit 513, the first gate 514, the first source-drain layer 515, the second gate 517, the second source-drain layer 518, the conductive unit 519, and the touch layer 520. That is, in this embodiment, in the light-shielding unit 513, the first gate 514, the first source-drain layer 515, the second gate 517, the second source-drain layer 518, the conductive unit 519, and the touch layer 520 whose side close to the backlight module can be provided with the first light-shielding layer 502. In the light-shielding unit 513, the first gate 514, the first source-drain layer 515, the second gate 517, the second source-drain layer 518, the conductive unit 519 and the touch layer 520 whose side away from the backlight module can be provided with the second light-shielding layer 503.

In this embodiment, the material of the first light-shielding layer 502 is an insulating layer material. The first through holes 523 are formed on the first light-shielding layer 502 on the first drain 5152. The first through hole 523 is mainly used for electrical connection between the first drain electrode 5152 and the common electrode 521. In other embodiments, the material of the first light-shielding layer 502 may also be a conductive material. When the material of the first light-shielding layer 502 is a conductive material, the array substrate 5 further includes a first insulating layer (not shown) disposed between the metal layer 501 and the first light-shielding layer 502. The second through hole (not shown) is provided on the first insulating layer between the first drain electrode 5152 and the first light-shielding layer 502. The first drain 5152 is electrically connected to the first light-shielding layer 502 through the second through hole. The first insulating layer is used to prevent the first light-shielding layer 502 from being in direct contact with the metal layer 501, so as to avoid electrical defects of the metal layer 501.

In this embodiment, the material of the first light-shielding layer 502 is an insulating layer material. The third through hole 524 is provided on the first light-shielding layer 502 on the second gate 517. The third through hole 524 is mainly used for electrical connection between the second gate 517 and the conductive unit 519. In other embodiments, the material of the first light-shielding layer 502 may also be a conductive material. When the material of the first light shielding layer 502 is a conductive material, the array substrate 5 further includes a first insulating layer (not shown) disposed between the metal layer 501 and the first light-shielding layer 502. The fourth through hole (not shown) is provided on the first insulating layer between the second gate 517 and the first light-shielding layer 502. The second gate 517 is electrically connected to the first light-shielding layer 502 through the fourth through hole. The first insulating layer is used to prevent the first light-shielding layer 502 from being in direct contact with the metal layer 501, so as to avoid electrical defects of the metal layer 501. In this embodiment, the material of the second light-shielding layer 503 is insulating material. The first source 5151, the first drain 5152, the second source 5181, the second drain 5182, and the second light-shielding layer 503 on the conductive unit 519 are all provided with the fifth through hole 525. The fifth through hole 525 is mainly used for electrically connecting the first source 5151, the first drain 5152, the second source 5181, the second drain 5182, and the conductive unit 519 with other elements.

In other embodiments, the material of the second light-shielding layer 503 may also be a conductive material. When the material of the second light-shielding layer 503 is a conductive material, the array substrate 5 further includes a second insulating layer (not shown) disposed between the metal layer 501 and the first light-shielding layer 502. The sixth through hole (not shown) is provided on the second insulating layer between the first source 5151, the first drain 5152, the second source 5181, the second drain 5182, the conductive unit 519, and the second light-shielding layer 503. The first source 5151, the first drain 5152, the second source 5181, the second drain 5182, and the conductive unit 519 are all electrically connected to the second light-shielding layer 503. The second insulating layer is used to prevent the second light-shielding layer 503 from being in direct contact with the metal layer 501, so as to avoid electrical defects of the metal layer 501.

The light-shielding unit 513, the first gate 514, the first source-drain layer 515, the second gate 517, the second source-drain layer 518, the conductive unit 519, and the touch layer 520 are all made of metal materials. For example: Ti or Mo or a combined structure of Mo and Al or a combined structure of Mo and Cu or a combined structure of Mo, Cu and IZO or a combined structure of IZO, Cu and IZO or a combination of Mo, Cu, and ITO or a combination of Ni, Cu, and Ni or a combined structure of MoTiNi, Cu, and MoTiNi or a combined structure of NiCr, Cu and NiCr or CuNb etc.

In this embodiment, the light-shielding unit 513, the first gate 514 and the second gate 517 are made of molybdenum. The first light-shielding layer 502 and the second light-shielding layer 503 on the light-shielding unit 513, the first gate 514, and the second gate 517 all include a molybdenum oxide film layer. The light-shielding unit 513 formed of molybdenum material, the first gate 514 and the second gate 517 and the first light-shielding layer 502 and the second light-shielding layer 503 formed of molybdenum oxide are coherent and destructive to reduce reflected light.

In this embodiment, the first source 5151, the first drain 5152, the second source 5181, the second drain 5182, and the conductive unit 519 are stacked structures of titanium/aluminum/titanium. In addition to the molybdenum oxide film layer, the first light-shielding layer 502 and the second light-shielding layer 503 on the first source 5151, the first drain 5152, the second source 5181, the second drain 5182, and the conductive unit 519 in addition to need a molybdenum oxide film layer, also need a molybdenum film layer between the molybdenum oxide film layer and the metal layer.

The reflected light is reduced through coherent and destructive mode between the molybdenum film layer and the molybdenum oxide film layer. Specifically, after the light passes through the molybdenum oxide film layer, it is reflected on the molybdenum film layer, and an interference effect occurs between the transmitted light passing through the molybdenum oxide film layer and the reflected light after being reflected by the molybdenum film layer, so as to realize interference extinction and reduce reflected light powerful. The thickness of the molybdenum oxide film layer and the total thickness of the molybdenum film layer range from 100 nm to 150 nm. Considering the feasibility of the process, the thickness of the molybdenum oxide film layer and the total thickness of the molybdenum film layer should be reduced as much as possible to facilitate the later planarization treatment. If the thickness of the molybdenum oxide film layer and the total thickness of the molybdenum film layer are too large, it will be difficult to achieve planarization, which may affect the planarity of subsequent film layers. In this embodiment, the total thickness of the molybdenum oxide film layer and the molybdenum film layer is 120 nm. The ratio of the thickness of the molybdenum oxide film layer to the thickness of the molybdenum film layer is in the range of ⅙-½. Generally, the thicker the molybdenum oxide film layer is, the worse the light transmission effect is. In order to ensure that light passing through the molybdenum oxide film layer does not pass through the molybdenum film layer, the thickness of the molybdenum film layer is generally greater than 50 nm.

As shown in FIG. 1, the liquid crystal layer 4 is disposed between the array substrate 5 and the color filter substrate 3.

As shown in FIG. 1, the second polarizer 6 is disposed on a side of the array substrate 5 away from the backlight module 1. The basic structure of the second polarizer 6 includes PVA (polyvinyl alcohol) and TAC (triacetyl cellulose) disposed on both sides of the PVA. It is the PVA layer that plays a polarizing role, but PVA is very easy to hydrolyze. In order to protect the physical properties of the polarizing film, a layer of (TAC) film with high light transmittance, good water resistance and certain mechanical strength is compounded on both sides of the PVA for protection. The polarization direction of the second polarizer 6 is perpendicular to the polarization direction of the first polarizer 2.

As shown in FIG. 1, the cover plate 7 is disposed on a side of the second polarizer 6 away from the backlight module 1. In this embodiment, the cover plate 7 is pasted on the side of the second polarizer 6 away from the backlight module 1 through an optical adhesive (OCA) 8. The cover plate 7 is mainly used to protect the film layer under it from being damaged by external force.

A display panel provided by the present application has been introduced in detail above. In this paper, specific examples are used to illustrate the principles and implementation methods of the present application. The descriptions of the above embodiments are only used to help understand the method and the core idea of the present application. Furthermore, for those skilled in the art, there will be changes in specific implementation methods and application scopes based on the idea of the present application. To sum up, the contents of this specification should not be understood as limiting the present application.

What is claimed is:

1. A display panel, comprising:
a backlight module;
a color filter substrate disposed on a side of the backlight module; and
an array substrate disposed on a side of the color filter substrate away from the backlight module;
wherein the array substrate comprises:
a first substrate;
a metal layer disposed on a side of the first substrate close to the backlight module; and
a first light-shielding layer disposed on a surface of a side of the metal layer close to the backlight module.

2. The display panel according to claim 1, wherein the array substrate further comprises:
a second light-shielding layer disposed on a surface of a side of the metal layer away from the backlight module.

3. The display panel according to claim 2, wherein both a reflectance of the first light-shielding layer and a reflectance of the second light-shielding layer are less than 10%.

4. The display panel according to claim 2, wherein the array substrate further comprises:
a first active layer disposed on a side of the first substrate close to the backlight module;
a first source-drain layer disposed on a side of the first active layer close to the backlight module, wherein the first source-drain layer comprises a first source and a first drain electrically connected to both ends of the first active layer;
a second active layer disposed on the same layer as the first active layer at intervals;
a second source-drain layer disposed on the same layer as the first source-drain layer at intervals, wherein the second source-drain layer comprises a second source and a second drain electrically connected to both ends of the second active layer;
wherein the metal layer comprises at least one of the first source-drain layer and the second source-drain layer.

5. The display panel according to claim 4, wherein when a material of the first light-shielding layer is an insulating material, a first through hole is provided on the first light-shielding layer on the first drain;
when a material of the first light-shielding layer is a conductive material, the array substrate further comprises a first insulating layer disposed between the metal layer and the first light-shielding layer, a second through hole is provided on the first insulating layer between the first drain and the first light-shielding layer, and the first drain is electrically connected to the first light-shielding layer through the second through hole.

6. The display panel according to claim 4, wherein the array substrate further comprises:
a first gate disposed on the side of the first active layer close to the backlight module, and disposed corresponding to the first active layer;
a second gate disposed on the same layer as the first gate at intervals, and disposed corresponding to the second active layer;
when a material of the first light-shielding layer is an insulating material, a third through hole is provided on the first light-shielding layer on the second gate;
when the material of the first light-shielding layer is a conductive material, the array substrate further comprises a first insulating layer disposed between the metal layer and the first light-shielding layer, a fourth through hole is provided on the first insulating layer between the second gate and the first light-shielding layer, and the second gate is electrically connected to the first light-shielding layer.

7. The display panel according to claim 6, wherein the first light-shielding layer and the second light-shielding layer on the first gate and the second gate comprise a molybdenum oxide film layer.

8. The display panel according to claim 7, wherein the first light-shielding layer and the second light-shielding layer on the first source, the first drain, the second source, and the second drain comprise a molybdenum film layer and the molybdenum oxide film layer;
a thickness of the molybdenum oxide film layer and a total thickness range of the molybdenum film layer ranges from 100 nm to 150 nm; a ratio range of the thickness of the molybdenum oxide film layer to a thickness of the molybdenum film layer ranges from ⅙ to ½.

9. The display panel according to claim 1, wherein the color filter substrate comprises:
a second substrate;
a reflective layer disposed on a side of the second substrate away from the backlight module;
a third light-shielding layer disposed on a side of the reflective layer away from the backlight module;
a plurality of openings penetrating through the third light-shielding layer and the reflective layer; and
a plurality of filter units filling the plurality of openings in a one-to-one correspondence.

10. The display panel according to claim 9, wherein a projection of the reflective layer on the second substrate coincides with a projection of the third light-shielding layer on the second substrate.

11. The display panel according to claim 9, wherein a reflectance of the reflective layer is greater than 60%.

12. A display panel, comprising:
a backlight module;
a color filter substrate disposed on a side of the backlight module; and
an array substrate disposed on a side of the color filter substrate away from the backlight module;
wherein the array substrate comprises:
a first substrate;
a metal layer disposed on a side of the first substrate close to the backlight module; and
a first light-shielding layer disposed on a surface of a side of the metal layer close to the backlight module, wherein a reflectance of the first light-shielding layer is less than 10%.

13. The display panel according to claim 12, wherein the array substrate further comprises:
a second light-shielding layer disposed on a surface of a side of the metal layer away from the backlight module wherein a reflectance of the second light-shielding layer is less than 10%.

14. The display panel according to claim 13, wherein the array substrate further comprises:
a first active layer disposed on a side of the first substrate close to the backlight module;
a first source-drain layer disposed on a side of the first active layer close to the backlight module, wherein the first source-drain layer comprises a first source and a first drain electrically connected to both ends of the first active layer;
a second active layer disposed on the same layer as the first active layer at intervals;
a second source-drain layer disposed on the same layer as the first source-drain layer at intervals, wherein the second source-drain layer comprises a second source and a second drain electrically connected to both ends of the second active layer;
wherein the metal layer comprises at least one of the first source-drain layer and the second source-drain layer.

15. The display panel according to claim 14, wherein when a material of the first light-shielding layer is an insulating material, a first through hole is provided on the first light-shielding layer on the first drain;
when a material of the first light-shielding layer is a conductive material, the array substrate further comprises a first insulating layer disposed between the metal layer and the first light-shielding layer, a second through hole is provided on the first insulating layer between the first drain and the first light-shielding layer, and the first drain is electrically connected to the first light-shielding layer through the second through hole.

16. The display panel according to claim 14, wherein the array substrate further comprises:
a first gate disposed on the side of the first active layer close to the backlight module, and disposed corresponding to the first active layer;
a second gate disposed on the same layer as the first gate at intervals, and disposed corresponding to the second active layer;
when a material of the first light-shielding layer is an insulating material, a third through hole is provided on the first light-shielding layer on the second gate;
when the material of the first light-shielding layer is a conductive material, the array substrate further comprises a first insulating layer disposed between the metal layer and the first light-shielding layer, a fourth through hole is provided on the first insulating layer between the second gate and the first light-shielding layer, and the second gate is electrically connected to the first light-shielding layer.

17. The display panel according to claim 16, wherein the first light-shielding layer and the second light-shielding layer on the first gate and the second gate comprise a molybdenum oxide film layer; the first light-shielding layer and the second light-shielding layer on the first source, the first drain, the second source, and the second drain comprise a molybdenum film layer and the molybdenum oxide film layer;
a thickness of the molybdenum oxide film layer and a total thickness range of the molybdenum film layer ranges from 100 nm to 150 nm; a ratio range of the thickness of the molybdenum oxide film layer to a thickness of the molybdenum film layer ranges from ⅙ to ½.

18. The display panel according to claim 12, wherein the color filter substrate comprises:
a second substrate;
a reflective layer disposed on a side of the second substrate away from the backlight module;
a third light-shielding layer disposed on a side of the reflective layer away from the backlight module;
a plurality of openings penetrating through the third light-shielding layer and the reflective layer; and
a plurality of filter units filling the plurality of openings in a one-to-one correspondence.

19. The display panel according to claim 18, wherein a projection of the reflective layer on the second substrate coincides with a projection of the third light-shielding layer on the second substrate, and a reflectance of the reflective layer is greater than 60%.

20. The display panel according to claim 19, wherein a reflectance of the third light-shielding layer is less than 10%, and a ratio range of an area of the third light-shielding layer to an area of the display panel is greater than or equal to 60%.
